(19) United States
(12) Patent Application Publication
(10) Pub. No.: US 2015/0096722 A1
(43) Pub. Date: Apr. 9, 2015

(54) SYSTEMS AND METHODS FOR COOLING DISK LASERS

(71) Applicant: Logos Technologies, LLC, Fairfax, VA (US)

(72) Inventors: Jason Zweiback, Diablo, CA (US); Claudio Filippone, College Park, MD (US)

(21) Appl. No.: 14/382,473

(22) PCT Filed: Mar. 4, 2013
(86) PCT No.: PCT/US2013/028918

§ 371 Date: Sep. 2, 2014

Related U.S. Application Data
(60) Provisional application No. 61/605,796, filed on Mar. 2, 2012.

(51) Int. Cl. H05K 7/20; H01S 3/04

(52) U.S. Cl. CPC H05K 7/20254; H01S 3/0407
USPC 165/104.33; 165/104.28

(57) ABSTRACT

A cooling device for cooling heat-generating devices such as disk laser according to a desired thermal profile to generate desired edge effects and optical properties. An example cooling device includes a back plate for supporting the heat-generating device. The back plate is part of a cooling device housing with a wall providing an enclosure that contains a nozzle member. The nozzle member encloses the cooling device housing on a side opposite the back plate. A nozzle coolant surface is formed on an end of the nozzle member. The nozzle coolant surface extends outward from its center to an edge to form a coolant chamber with the back plate. Coolant fluid may enter the coolant chamber through inlet paths formed in the nozzle member and exit through a chamber gap between the nozzle coolant surface edge and inside of the housing wall.

### RELATED APPLICATIONS

This application claims priority to provisional patent application U.S. App. Ser. No. 61/605,796 titled “Method for Minimizing Optical Distortions in Disk Laser,” by Jason Zweiback and Claudio Filippone, filed on Mar. 2, 2012, and which is incorporated herein by reference.

### TECHNICAL FIELD

The present invention relates generally cooling heat-generating devices, and more particularly, to devices and methods for cooling heat-generating devices according to a selected thermal profile.

### BACKGROUND

Disk lasers are lasers having a laser material formed as a flat, substantially thin layer mounted on a heat sink. Disk lasers are also known as “active mirrors,” because the gain medium of a disk laser is essentially an optical mirror with a reflection coefficient greater than unity. A light is directed to the disk laser, and reflected off the disk laser at an intensity that is greater than the light directed to the disk laser. The disk layer is mounted on the heat sink to remove the substantial heat generated by the disk laser.

The heat sink may have a liquid coolant flowing near the surface of the disk laser to remove the heat. The structure of the heat sink may include cooling microchannels through which the coolant may flow providing a substantially uniform cooling effect across the surface of the disk. The coolant is pumped through the microchannels, however, due to pump non-uniformity and edge effects, a thermal gradient may form on the surface of the disk. This gradient distorts the disk resulting in optical aberrations. In some implementations, deformable mirrors and passive optics may be used to correct the optical aberrations. However, the added optical components add significantly to the cost and complexity of the laser system.

In view of the foregoing, there is an ongoing need for a system and method for cooling the disk laser in a manner that reduces optical aberrations caused by thermal gradients.

### SUMMARY

In view of the above, a cooling device is provided for cooling a heat-generating device. In one example, a cooling device comprises a back plate comprising a heat-receiving surface for supporting a heat-generating device, an opposing inner back plate surface, and a back plate thickness between the heat-receiving surface and the inner back plate surface. A housing extends from the back plate and includes a coolant outlet. A nozzle member is disposed in the housing and spaced from the inner back plate surface to form a coolant chamber therebetween. The nozzle member includes a coolant inlet and is configured for establishing a coolant fluid flow through the coolant chamber from the coolant inlet to the coolant outlet. The shape of at least one of the back plate, the coolant chamber, and the nozzle member is varied to establish a non-uniform heat transfer profile from the heat-generating device to the coolant chamber to impart a desired temperature profile in the heat-generating device.

In other examples, the cooling device includes the housing without a back plate.

In other examples, the coolant chamber is formed with the inner back plate surface and the nozzle coolant surface contoured to converge from the center to the edge of the coolant chamber. The convergence may be designed to tailor the cooling according to a desired thermal profile.

In other examples, the coolant chamber is formed with the inner back plate surface and the nozzle coolant surface contoured to diverge from the center to the edge of the coolant chamber. The divergence may be designed to tailor the cooling according to a desired thermal profile.

In other examples, the cooling device may include a peripheral channel surrounding the nozzle member such that the coolant fluid drains into the peripheral channel from the chamber gap.

In some examples, a coolant exit chamber may be formed to surround the cooling device housing. The coolant exit chamber may have a cross-section that varies as it extends around the cooling device housing.

In other examples, multiple fluid inlet paths may be formed in the nozzle member. The multiple fluid inlet paths may be injected with fluid using individually controlled injectors to provide a coolant flow in each injector that is tailored to generate a desired cooling profile.

In other examples, the fluid inlet path may be designed to generate turbulence using, for example, swirl vanes.

Other devices, apparatus, systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood by referring to the following figures. The components in the figures are not necessarily to scale, emphasis instead being placed upon illustrating the principles of the invention. In the figures, reference numerals designate corresponding parts throughout the different views.

FIG. 1 is a top perspective cross-sectional view of an example implementation of a cooling device.

FIG. 2A is a top perspective view of the example implementation shown in FIG. 1.

FIG. 2B is a bottom perspective view of the example implementation shown in FIG. 1.

FIG. 3 is a top perspective cross-sectional view of an example implementation of a modified version of the cooling device shown in FIG. 1.

FIG. 4 is a bottom perspective cross-sectional view of an example implementation of another modified version of the cooling device in FIG. 1.

FIG. 5 is a cross-sectional view of an example implementation of a modified version of the cooling device shown in FIG. 4.

FIG. 6 is a schematic cross-sectional view of an example of a cooling device having dual coolant chambers.

FIG. 7 is a cross-sectional view of an example implementation of the cooling device illustrated in FIG. 6.

FIG. 8 is a schematic cross-sectional view of another example of a cooling device that delivers coolant using individually controlled injectors.

FIG. 9 is a cross-sectional view of an example implementation of the cooling device illustrated in FIG. 8.

FIG. 10 is a top view of another example implementation of a cooling device.

### DETAILED DESCRIPTION

Heat generating devices such as disk lasers generate heat from its volume in a manner that conforms to a thermal profile that characterizes the distribution of heat generated within the volume of the device. In general, the thermal profiles of disk lasers are not uniform such that the same amount of heat is generated from any location within the disk. Disk lasers typically generate the most heat from the center of the heat-generating device, and less heat from points out towards the edges of the disk. The thermal profile may yet vary in terms of, for example, how hot the hottest portion gets, how much the temperature varies along the surface of the disk, and the difference between the hottest portion and the coolest portion of the disk. In addition, a disk laser may exhibit optical properties that may distort the optical properties of the disk laser despite achieving a uniform temperature profile. The cooling devices described herein are advantageously constructed to provide cooling according to a desired thermal profile that addresses resulting desired optical properties in the performance of the laser in addition to providing a more uniform thermal profile for the disk laser.

The cooling devices described below are described in the context of providing cooling for a disk-shaped heat-generating device, and more particularly for a disk laser. Those of ordinary skill in the art will understand that the cooling devices may be configured for cooling any heat-generating device having flat surfaces separated by a thickness. The device may also be any shape such as round, rectangular or polygonal.

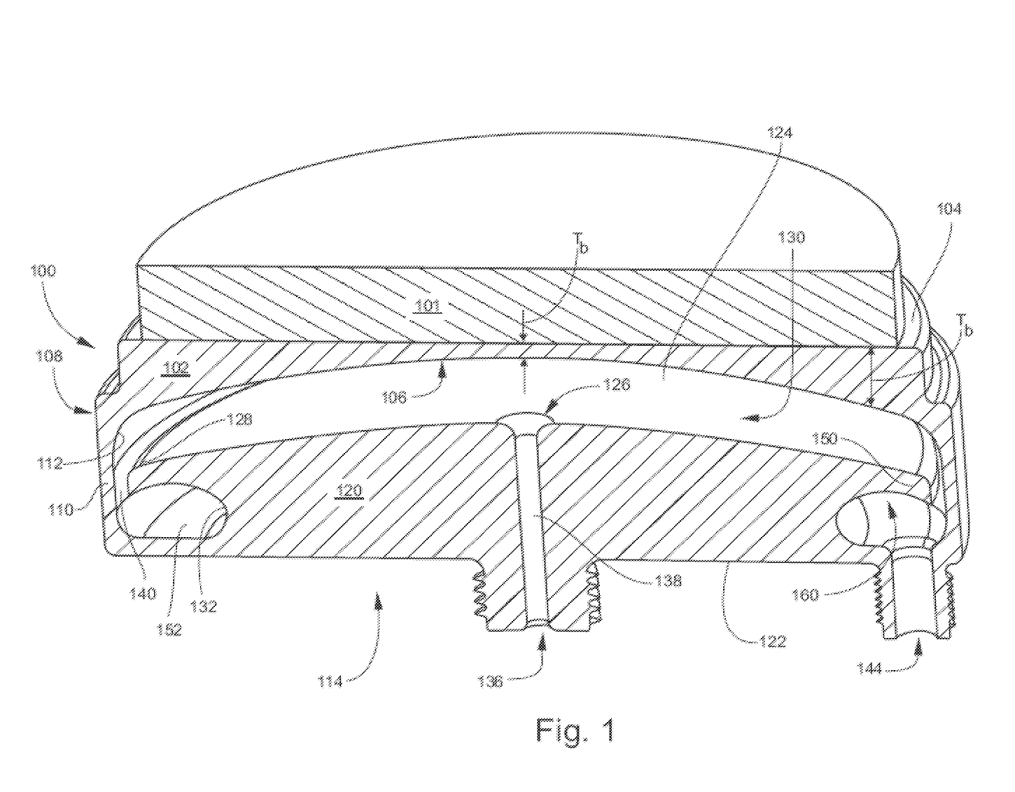

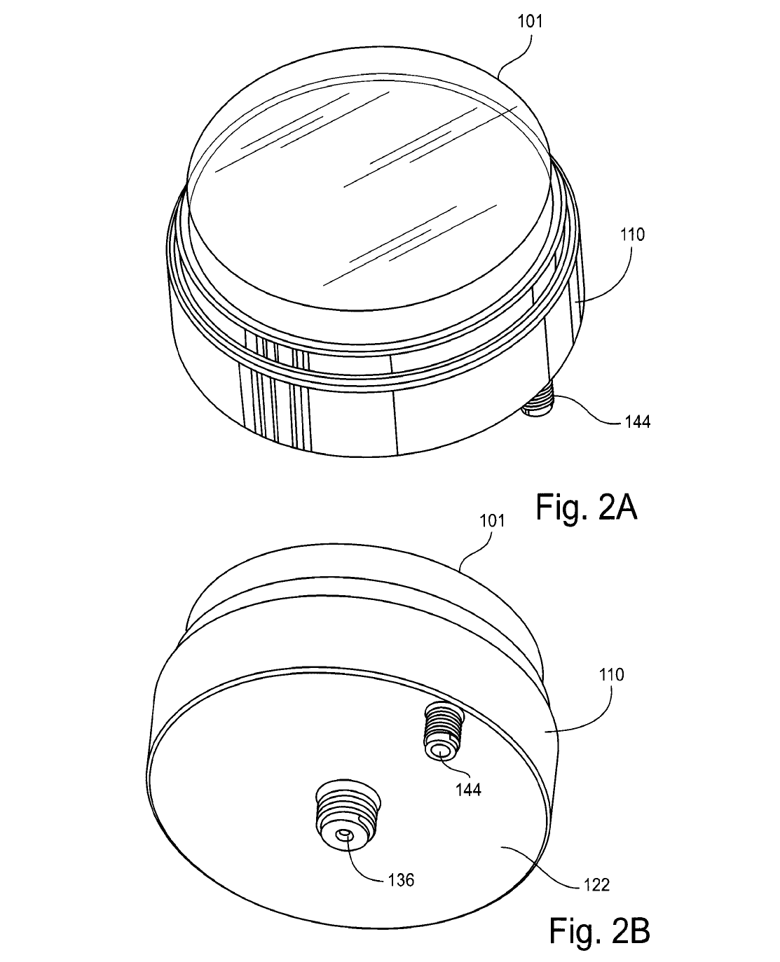

FIG. 1 is a top perspective cross-sectional view of an example implementation of a cooling device 100 configured to provide cooling for a heat generating device 101 such as a disk laser. FIG. 2A is a top perspective view of the example implementation shown in FIG. 1. FIG. 2B is a bottom perspective view of the example implementation shown in FIG. 1. Referring to FIGS. 1, 2A, and 2B, the cooling device 100 includes a back plate 102 comprising a heat receiving surface 104 on which the heat generating device 101 is mounted. The heat generating device 101 is substantially flat with a thickness between flat surfaces. In general, the thickness between the flat surfaces is uniform so that the heat-generating device 101 is substantially planar. The heat-generating device 101 may also have a linear thickness or curved thickness with at least one flat surface. As noted above, the heat generating device 101 is assumed to be a disk laser for purposes of providing a description, however, any device having a planar surface of any shape that generates heat sufficient to require cooling may be the heat generating device 101.

The heat receiving surface 104 of the back plate 102 has an area sufficient to contact the planar surface of the heat generating device 101. The back plate 102 may be made of a heat conducting solid shaped to form an inner back plate surface 106 disposed opposite the heat receiving surface 104. The inner back plate surface 106 may be contoured to vary a back plate thickness, T_{b}, between the heat receiving surface 104 and the inner back plate surface 106. The back plate thickness T_{b} of the back plate 102 in FIG. 1 varies from a small thickness in a central portion of the back plate 102 to a larger thickness toward the outer edge of the back plate 102. The back plate 102 contributes to cooling of the heat-generating device 101 through conduction in the heat-conducting solid material. As described below, a coolant medium is injected to contact the inner back plate surface 106 and thus provide cooling via convection. The geometry of the back plate 102 may be designed to provide the combined effects of heat conduction and convection to cool the heat-generating device 101 in accordance with a desired thermal profile for the surface of the heat generating device 101.

The cooling device 100 includes a cooling device housing 108 formed by the back plate 102 on one side and a housing wall 110 extending from the back plate 102 to surround the cooling device housing 108. The housing wall 110 comprises an inner wall surface 112 extending from the inner back plate surface 106. The housing wall 110 is formed to surround the cooling device housing 108 between a coolant access side 114 and the back plate 102.

The cooling device 100 includes a nozzle member 120 disposed inside the cooling device housing 108. The nozzle member 120 includes a nozzle member base 122 that covers the coolant access side 114 of the cooling device housing 108. The nozzle member base 122 substantially encloses the cooling device housing 108. A nozzle coolant surface 124 in the cooling device housing 108 is formed on one end of the nozzle member 120 opposite the nozzle member base 122. The nozzle coolant surface 124 extends outward from a nozzle coolant surface center 126 to a nozzle coolant surface edge 128. The nozzle coolant surface 124 is formed to create a coolant chamber 130 on one side and with the inner back plate surface 106 on the other side to form a volume that may be used to contain a coolant fluid. The nozzle member 120 includes a nozzle body wall 132 that surrounds the nozzle member 120 between the nozzle coolant surface 124 and the nozzle member base 122.

The cooling device 100 includes a coolant inlet 136 formed in the nozzle member 120 to provide a fluid inlet path 138 between the nozzle member base 120 and the nozzle coolant surface 124. The coolant inlet 136 is configured to receive coolant fluid and to inject the coolant fluid into the fluid inlet path 138. The fluid inlet path 138 drains the coolant fluid into the coolant chamber 130 at the nozzle coolant surface center 126. A chamber gap 140 is formed in the coolant chamber 130 between the nozzle body wall 132 and the inner wall surface 112 of the housing wall to drain coolant from the coolant chamber 130. The chamber gap 140 is formed as an annular gap surrounding the nozzle member 120 for the cooling device 100 in FIGS. 1, 2A, and 2B. In alternative implementations, the chamber gap 140 may follow a rectangular perimeter, or a polygonal perimeter, and the shape formed by the chamber gap 140 may or may not correspond to the shape of the heat-generating device 101.

The cooling device 100 is configured to permit cooling fluid to enter the coolant chamber 130 and fill the coolant chamber 130 so that the cooling fluid contacts the inner back plate surface 106 providing a cooling effect by convection. The cooling fluid drains from the coolant chamber 130 via the chamber gap 140. A coolant outlet 144 is formed in the nozzle member base 122 in a location suitable to provide an exit for coolant fluid that flows into the chamber gap 140.

In the cooling device 100 shown in FIGS. 1, 2A, and 2B, the geometry of the coolant chamber 130 may be selectively formed according to the design of the contour of the inner back plate surface 106 and the nozzle coolant surface 124 to conform to a desired thermal profile. In an example implementation of the cooling device 100 in FIG. 1, the nozzle member 120 may include a nozzle ledge 150 that may be formed by the nozzle coolant surface edge 128 extending over the nozzle body wall 132.

The nozzle member 120 may also include a nozzle member inner surface 152 extending from the nozzle body wall 132 opposite the nozzle member base 122 thereby forming a floor for a peripheral channel 160. As shown in FIG. 1, the peripheral channel 160 may be formed by the nozzle ledge 150, the nozzle body wall 132, the nozzle member inner surface 152, the inner wall surface 112 of the housing wall 110 and the chamber gap 140. The coolant outlet 144 may also be formed in the peripheral channel 160 at a location suitable to sufficiently drain the cooling fluid from the cooling device 100. When in use, the cooling device 100 receives a coolant fluid through the fluid inlet path 138, which fills the coolant chamber 130. As the coolant fluid fills the coolant chamber 130, the coolant fluid provides cooling to the heat generating device 101 via the back plate 102 by cooling convection on the inner back plate surface 106. As the coolant fluid fills the coolant chamber 130, coolant fluid flows into the chamber gap 140 to fill the peripheral channel 160. As the peripheral channel 160 fills with coolant fluid, it is flushed out through the coolant outlet 144 which may be formed in the peripheral channel 160.

The cooling of the heat-generating device 101 may be configured to cool in accordance with a desired thermal profile by configuring the geometry of the coolant chamber 130 as described above addressing the following parameters:
1. Volume of the fluid inlet path 138,
2. Fluid velocity of cooling fluid flowing in fluid inlet path 138,
3. Fluid velocity of cooling fluid flowing in the coolant chamber 130 sufficient to contact the inner back plate surface 106.
4. Diameter of cross-section of coolant chamber 130.
5. The change in separation distance between the inner back plate surface 106 and the nozzle coolant surface 124 in order to determine cooling by convection on any point of the inner back plate surface 106.
6. The thickness Tb of the back plate 102.
7. Determining a chamber gap 140 distance that permits a controlled flow of the coolant fluid in the coolant chamber 130,
8. Determining a volume for the peripheral channel 160 that holds a desired coolant fluid volume as the coolant fluid drains through the coolant outlet 144.

These parameters may be inter-related so that a change in fluid velocity, for example, may be achieved by changes in shape and dimensions of the coolant chamber 130, fluid inlet path 138, and other elements of the cooling device. The approach to these parameters, the values selected, the shapes selected, and the materials used for the cooling device 101 in FIGS. 1, 2A, & 2B contribute to achieving the desired thermal profile.

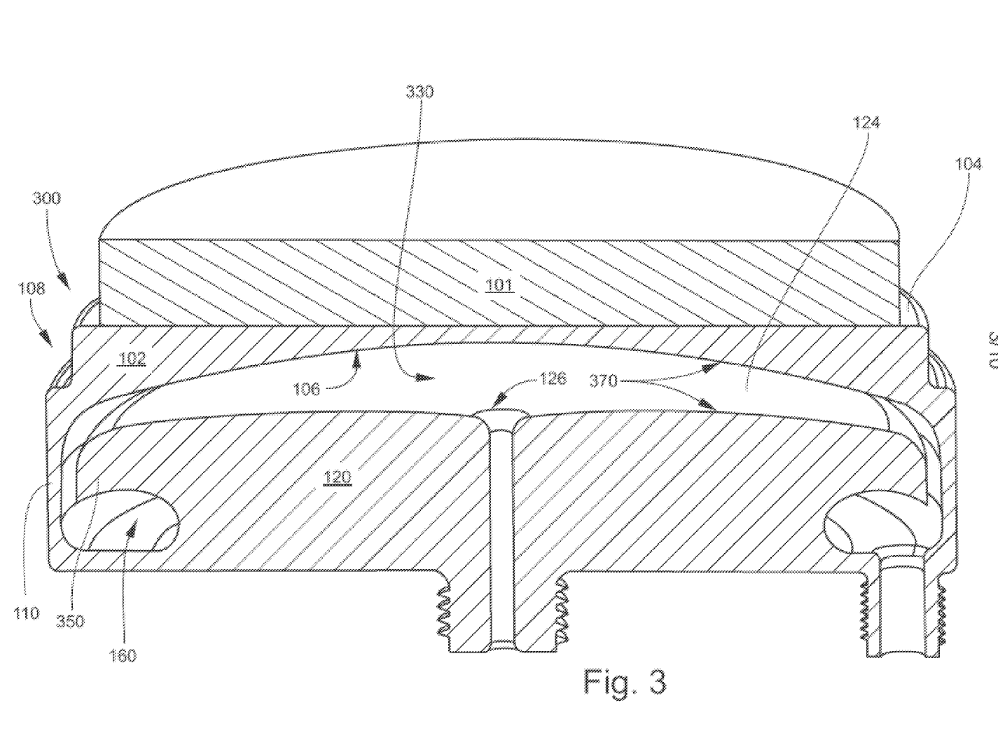

FIG. 3 illustrates how a configuration may be adjusted to affect the cooling response that contributes to the desired thermal profile. FIG. 3 is a top perspective cross-sectional view of an example implementation of a modified version of the cooling device 300 shown in FIG. 1. The cooling device 300 in FIG. 3 is similar to the cooling device 100 in FIG. 1 except for differences in the volume of the coolant chamber 130 and in the geometry of the nozzle member 120. It is noted that the cooling device 100 effects a cooling of the heat-generating device 101 by combining the effects of conducting heat away from the heat-generating device 101 with a heat-conducting solid and injecting a coolant fluid on the heat-conducting solid to cool by convection. Modifications may be made to affect the cooling effect of each.

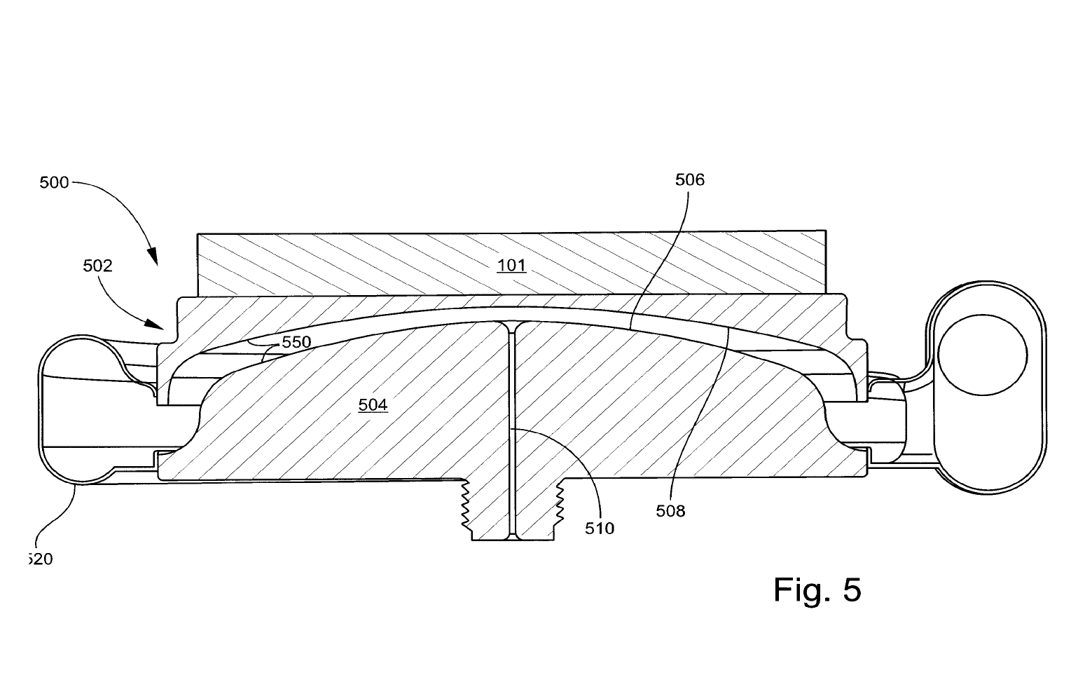

As shown in FIG. 3, the cooling device 300 includes components such as the back plate 102, the heat receiving surface 104, the cooling device housing 108, and the nozzle member 120 that are similar to the corresponding components in the cooling device 100 in FIG. 1. However, the geometry and volume of the coolant chamber 130 has been modified to provide a coolant chamber 330 in FIG. 3 that cools according to a different thermal profile than that of FIG. 1. The coolant chamber 130 in FIG. 1, which is formed by the nozzle coolant surface 124 and the inner back plate surface 106, cools more evenly from center to periphery due to a relatively constant spacing between the inner back plate surface 106 and the nozzle coolant surface 124. The coolant chamber 330 in FIG. 3 has a relatively deeper separation between the inner back plate surface 106 and nozzle coolant surface 124 at the nozzle coolant surface center 126. The contours of the inner back plate surface 106 and nozzle coolant surface 124 also converge at 370. The converging coolant chamber 330 in FIG. 3 is used to control the fluid velocity in order to adjust the heat transfer to obtain the desired thermal profile in the heat-generating device 101. A similar effect is illustrated using a coolant chamber with diverging contours as described below with reference to FIG. 5.

The converging contours of the coolant chamber 330 in FIG. 3 changes the manner in which the cooling device 300 cools by convection. Modifications may be made that affect the manner in which cooling is effected by conduction. For example, the nozzle member 120 in FIG. 3 may include a nozzle ledge 350 that is thicker than the nozzle ledge 150 shown in FIG. 1, which may provide more of a temperature difference between the coolant fluid in the coolant chamber 350 and the coolant fluid flowing in the peripheral channel 160 waiting to drain out of the cooling device 100.

It is noted that the cooling in accordance with a desired thermal profile may be achieved by applying principles of fluid dynamics and thermodynamics using variables selected from the parameters listed above. It is also noted that the list of parameters above is not intended to be an exhaustive list. Other parameters may be addressed in the design of particular implementations of the cooling device. Additional parameters may relate for example to the coolant fluids and heat-conducting solid materials that may be selected to implement a particular cooling device 100. Examples of coolant fluids that may be used in a cooling device include air, water, sodium, lithium, gallium, gallium alloys, liquid nitrogen, ammonia, acetone, hydrocarbons, fluorocarbons, and propylene glycol. It is to be understood that this list of coolant fluids are listed as examples of coolant fluids that may be used with any implementation of a cooling device. This list is not intended to be limiting. Any coolant with the proper thermo-physical properties can be employed in any implementation. Examples of coolants that may be used also include refrigerant fluids or materials that involve cooling by phase change.

Examples of heat-conducting solid materials that may be used in a particular cooling device 100 include tungsten, copper, a copper-tungsten alloy, gold, silver, aluminum, beryllium, and beryllium-copper. These solid materials are listed as examples of materials that may be used in implementations of a cooling device. The list is not intended to be limiting as any suitable heat-conducting solid material may be used in accordance with the requirements of a given implementation.

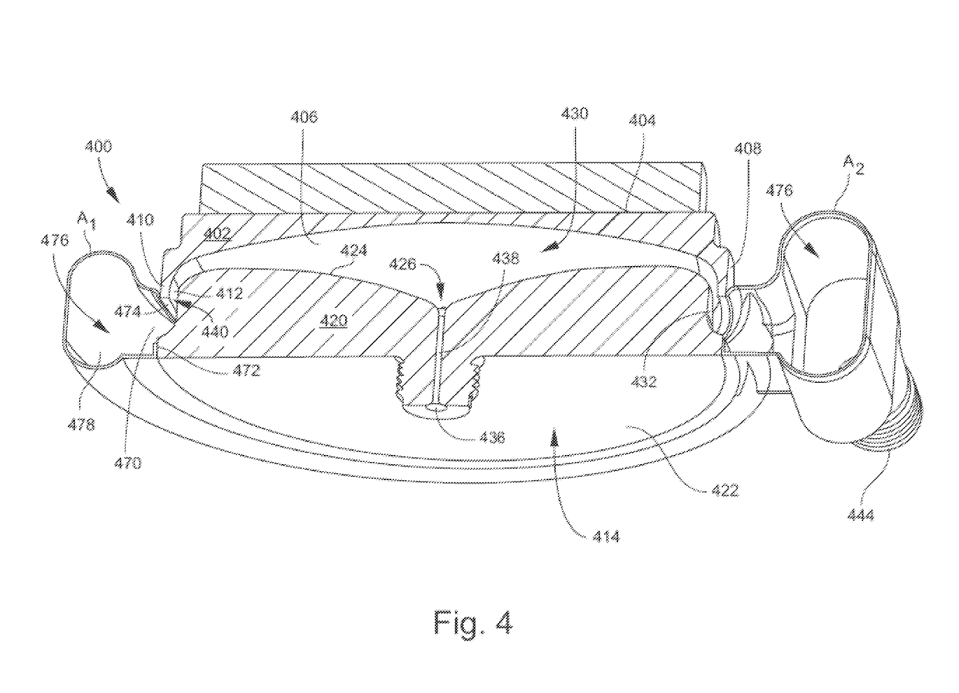

FIGS. 4 and 5 illustrate another manner in which cooling may be tuned according to a desired thermal profile. FIG. 4 is a bottom perspective cross-sectional view of an example implementation of another modified version of the cooling device 400 in FIG. 1. FIG. 5 is a cross-sectional view of an example implementation of a modified version of the cooling device shown in FIG. 4.

Referring to FIG. 4, the cooling device 400 comprises many elements similar to those of the cooling device 100 shown in FIG. 1. The cooling device 400 includes a back plate 402, which has an inner back plate surface 406 formed on a side opposite the heat receiving surface 404. The inner back plate surface 406 in FIG. 4 may also be contoured to vary the thickness of the back plate 402 from the center to the edge of the back plate 402. The cooling device 100 in FIG. 4 includes the cooling device housing 108 formed by the back plate 402 on one side and a modified housing wall 410. The modified housing wall 410 extends from the back plate 402 to surround the cooling device housing 408 with the inner wall surface 412 extending from the inner back plate surface 406. The cooling device housing 408 houses a nozzle member 420 comprising a nozzle member base 422, a nozzle coolant surface 424, a fluid inlet path 438, and a nozzle body wall 432 between the nozzle member base 422 and the nozzle coolant surface 424.

The modified housing wall 410 in FIG. 4 only extends partially towards the nozzle member base 422. A nozzle base perimeter 472 surrounds the nozzle member base 122 to define an edge of the nozzle member base 122. A chamber wall opening 470 is formed between a chamber wall edge 474 of the modified wall housing 410 and the nozzle base perimeter 472. The cooling device 400 in FIG. 4 includes a coolant exit chamber 476 comprising an exit chamber surface 478 extending from the nozzle member base perimeter 472 around to the chamber wall edge 474. The exit chamber surface 478 forms a tube-like structure configured to collect coolant fluid that flows into the coolant exit chamber 476 via the chamber gap 140 and through the chamber wall opening 470. The tube-like structure may comprise a varying cross-sectional area that increases from a smallest cross-sectional area A₁ around the cooling device housing 408 to a largest cross-sectional area A₂.

In use, the coolant chamber 430 is filled with coolant fluid at a selected velocity. As the coolant chamber 430 fills with coolant fluid, which then drains into the coolant exit chamber 476 via a chamber gap 440 between the nozzle coolant surface edge 428 and the inner wall surface 412 of the wall housing 410. The coolant exits the cooling device 400 through a coolant outlet 444 positioned near where the coolant exit chamber 476 has the largest cross-sectional area.

FIG. 5 depicts a cooling device 500 similar to the cooling device 400 in FIG. 4. The cooling device 500 has a back plate 502 with an inner back plate surface 508, a nozzle member 504 with a nozzle coolant surface 506, a fluid inlet path 510, and a coolant exit chamber 520. The cooling device 500 in FIG. 5 is configured such that the inner back plate surface 508 and the nozzle coolant surface 506 form diverging contours from the center to the edge of the coolant chamber. The diverging contours of the inner back plate surface 508 and the nozzle coolant surface 506 provides an increased fluid velocity in the coolant chamber increasing the cooling effect by convection.

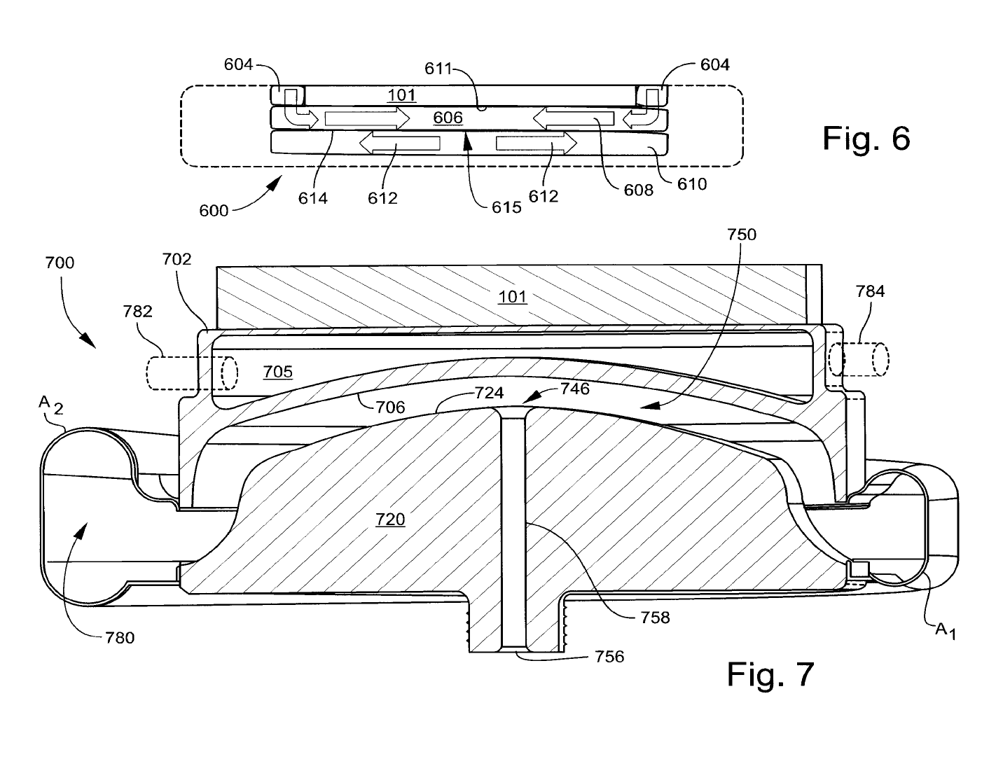

The cooling devices 100, 300, 400, and 500 in FIGS. 1, 3, 4, and 5, respectively, provide cooling according to a desired thermal profile by adding a convection cooling to a heat conducting cooling device housing by delivering a flow of coolant fluid into a coolant chamber shaped so that the combined convection and conduction cooling effects follow a desired thermal profile. In other example implementations, cooling by convection may be modified by injecting the coolant fluid directly onto the heat-generating device, or to a heat-conducting component such as the back plate 102 (in FIG. 1). Cooling devices may be further configured to cool according to a desired thermal profile by providing for the use of more than one coolant fluid. FIG. 6 is a schematic cross-sectional view of an example of a cooling device 600 having a dual coolant chamber system. The cooling device 600 in FIG. 6 includes a first coolant chamber 606 and a second coolant chamber 610. The first coolant chamber 606 provides for a first coolant 608 to flow at a first thermal interface 611 with the heat-generating device 101. The second coolant chamber 610 provides for a second coolant 612 to flow at a second thermal interface 614 with the first coolant chamber 606. The first coolant chamber 606 may include ports 604 for entry and/or exit of the first coolant 608. Alternatively, the first coolant chamber 606 may be closed.

The first thermal interface 610, the second thermal interface 614, and the third thermal interface 615 are illustrated schematically in FIG. 6. An implementation of the cooling device 600 may include physical barriers between the first coolant chamber 606 and the second coolant chamber 610. The first thermal interface 611 may or may not involve a physical barrier. A third thermal interface 615 may be formed at around the center of the cooling device 600 between the first coolant chamber 806 and the second coolant chamber 610. The properties of the third thermal interface 615 may be adjusted for example by an appropriate setting of the thickness of the heat-conducting solid between the first coolant chamber 606 and the second coolant chamber 610. The thickness in the area around the center of the cooling device 600 and the materials selected for a barrier between the first coolant chamber 606 and the second coolant chamber 610 (based on the thermal conductivity K of the selected material) may provide a change in the heat transfer characteristics between the first coolant 608 and the second coolant 612 and thereby form the third thermal interface 615.

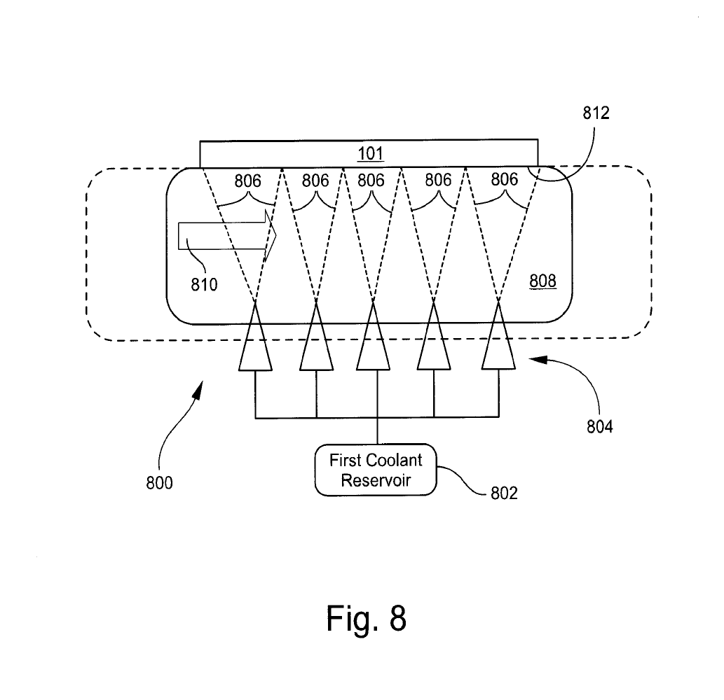

It is noted that the example shown in FIG. 6 is a schematic representation of a cooling device that uses more than one cooling fluid. FIG. 7 is a cross-sectional view of an example implementation of a cooling device 700 of the type illustrated in FIG. 6.

The cooling device 700 in FIG. 7 comprises a back plate 702 with an inner back plate surface 706 similar to the back plate 102 shown in the cooling device 100 in FIG. 1 except that a first coolant chamber 705 is contained in the back plate 702. The cooling device 700 also includes a nozzle member 720 with a nozzle coolant surface 724 and a coolant exit chamber 780 surrounding the cooling device 700 with a cross sectional area that increases from a smallest cross-sectional area A₂ to a largest cross-sectional area A₁. A second coolant chamber 750 is formed in the cooling device 700 between the inner back plate surface 706 and the nozzle coolant surface 724.

The first coolant in the cooling device 700 in FIG. 7 is contained in the first coolant chamber 705. The first coolant chamber 705 in FIG. 7 is a closed chamber, which may contain a coolant with desired heat-conducting properties. The first coolant in the first coolant chamber 705 may also include a coolant that circulates passively inside the chamber from areas of high thermal loads to areas of lower temperatures, thereby providing a mechanism that makes temperature uniform across the heat-generating device 101.

The first coolant chamber 705 may also include an inlet port 792 and an outlet port 794 (outlined with dashed line to emphasize that the inlets are optional) to provide a flow of coolant through the first coolant chamber 705. The first and second coolants may be any suitable coolant as discussed above with reference to the cooling device 100 shown in FIG. 1. Where two different coolants selected, any suitable combination of coolant fluids may be implemented.

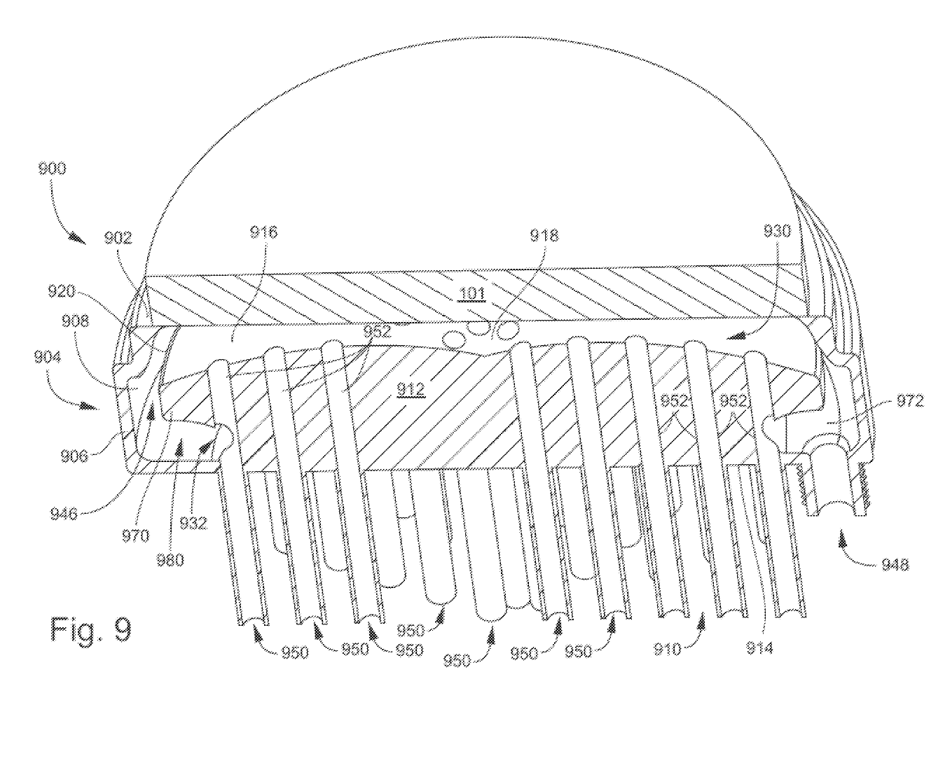

FIG. 8 is a schematic cross-sectional view of another example of a cooling device 900 that adds coolant injection to spray or stream the coolant fluid on to the heat-generating device 101 or to a material that is conducting heat from the heat-generating device 101. The cooling device 900 illustrated schematically in FIG. 8 includes a coolant chamber 808 configured to receive coolant from a plurality of injectors 804. The plurality of injectors 804 receive coolant from a coolant reservoir 802 and inject the coolant fluid into the coolant chamber 808 as shown at 806 to cool the device 101 at a thermal interface 812. A second coolant fluid 810 may be provided to remove vapors of the first coolant fluid and to provide further cooling. The injectors 804 may be individually controlled to cool in accordance with a selected thermal profile. In an example implementation, the injectors 804 may be controlled individually in real-time. During use, the thermal profile of a disk laser, for example, may change due to changes in room temperature, air currents, pump power variations, for example, and other possible affects. The multiple injectors 804 may be controlled to compensate for changes actively, in real-time, when the changes are detected.

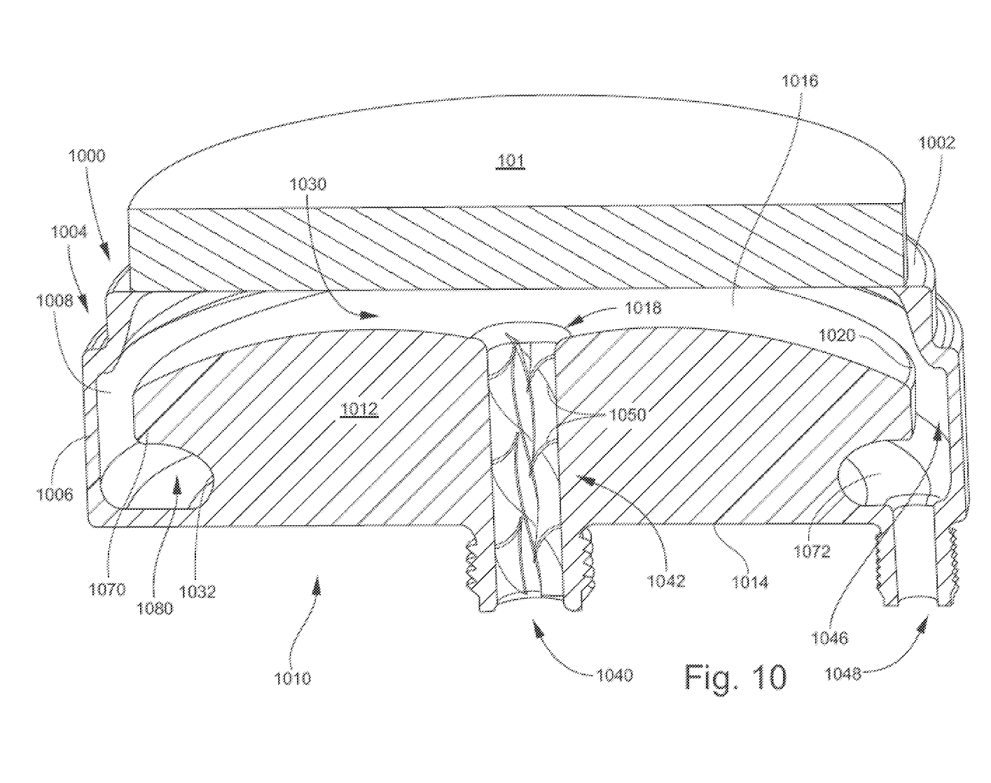

FIG. 9 is a cross-sectional view of an example implementation of the cooling device 900 schematically illustrated in FIG. 8. The cooling device 900 in FIG. 9 includes a device-supporting surface 902 on which the heat-generating device 101 is mounted. The device-supporting surface 902 is an annular area that is sufficient to contact a surface of the heat-generating device 101 along a peripheral area substantially along a perimeter of the heat-generating device 101. It is noted that the device-supporting surface 902 is an annular area for purposes of supporting a disk. The actual shape of the surface area would depend on the specific shape of the heat-generating device 101 that is supported.

The cooling device 900 includes a cooling device housing 904 formed by the heat-generating device 101 on one side when mounted on the device-supporting surface 902 and by a housing wall 906, which surrounds the cooling device housing 904. The housing wall 906 includes an inner wall surface 908 extending from the device-supporting surface 902. The housing wall 906 surrounds the cooling device housing 904 between a coolant access side 910 and the device-supporting surface 902.

The cooling device 900 includes a nozzle member 912 disposed in the cooling device housing 904. The nozzle member 912 includes a nozzle member base 914, which substantially covers the coolant access side 910 of the cooling device housing 904 and provides an enclosure for the cooling device housing 904. A nozzle coolant surface 916 is formed on an end of the nozzle member 912 opposite the nozzle member base 914. The nozzle coolant surface 916 extends outward from a nozzle coolant surface center 918 to a nozzle coolant surface edge 920. The nozzle coolant surface 916 forms a coolant chamber 930 with the heat-generating device 101 when mounted on the device-supporting surface 902. The nozzle member 912 includes a nozzle body wall 932 surrounding the nozzle member 912 between the nozzle coolant surface 916 and the nozzle member base 914. A plurality of fluid conduits 950 extends from the nozzle member base 914 to provide an input for an injector 804 (in FIG. 9A) to inject a coolant fluid. A plurality of corresponding fluid inlet paths 952 are distributed through the nozzle member 912 and formed to extend from the nozzle member base 914 to the nozzle coolant surface 916.

A chamber gap 946 is formed between the nozzle body wall 932 and the inner wall surface 908 of the housing wall 906 to allow the coolant to drain from the coolant chamber 930. The nozzle member 912 in FIG. 9B includes a nozzle ledge 970 formed by the nozzle coolant surface edge 920 extending over the nozzle body wall 932. A nozzle member inner surface 972 extends from the nozzle body wall 932 opposite the nozzle member base 914. A peripheral channel 980 is formed by the nozzle ledge 970, the nozzle body wall 932, the nozzle member inner surface 972, the inner wall surface 908 of the housing wall 904, and the chamber gap 946. A coolant outlet 948 is formed in the peripheral channel 980 to provide an exit for coolant fluid flowing in from the chamber gap 946.

In use, the cooling device 900 in FIG. 9 provides cooling by injecting fluid coolant into the coolant chamber 930 using a plurality of injectors connected to corresponding fluid conduits 950. The plurality of injectors may be individually controlled to deliver coolant at a selected fluid velocity based on the location of the individual fluid inlet paths 952 in the nozzle member 912 to adjust the cooling of the heat-generating device 101 at a location on the heat-generating device 101 that corresponds to the location of the individual fluid inlet path 952. In this way, the overall thermal profile of the heat-generating device 101 may be controlled.

It is noted that various features or elements of the examples of the cooling devices described herein may be combined in different configurations to tune the cooling effect of the cooling device to a desired thermal profile. For example, the cooling device 900 shown in FIG. 9 uses a plurality of fluid inlet paths 952 that spray coolant on to the heat-generating device 101 directly. The cooling device 900 may also be provided with a single fluid inlet path that provides a flow of coolant fluid to directly cool the heat-generating device 101 by convection. Such a cooling device may be implemented as a cooling device of the type shown in FIG. 1 without a back plate 102 (in FIG. 1).

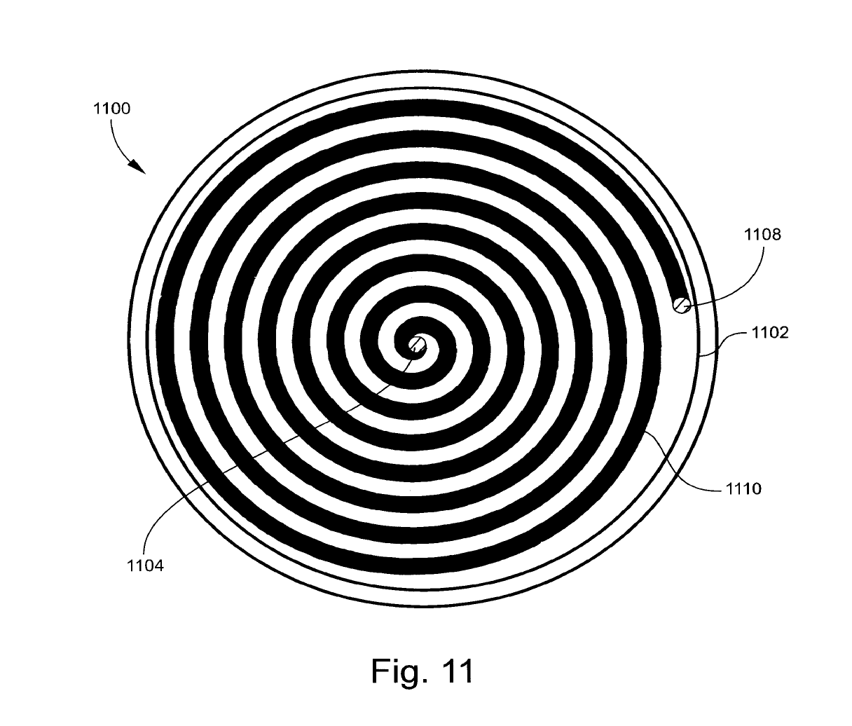

The fluid inlet path 138 (in FIG. 1) may also be modified in a cooling device using a single fluid inlet path with no back plate to generate turbulence to cool by convection with turbulence. FIG. 10 is a cross-sectional view of an example implementation of a cooling device 1000 configured to provide cooling by turbulence. The cooling device 1000 in FIG. 10 includes a coolant device housing 1004 formed by the heat-generating device 101 on one side when mounted on a device-supporting surface 1002 and by a housing wall 1006, which surrounds the cooling device housing 1004. The housing wall 1006 includes an inner wall surface 1008 extending from the device-supporting surface 1002. The housing wall 1006 surrounds the cooling device housing 1004 between a coolant access side 1010 and the device-supporting surface 1002.

The cooling device 1000 includes a nozzle member 1012 disposed in the cooling device housing 1004. The nozzle member 1012 includes a nozzle member base 1014, which substantially covers the coolant access side 1010 of the cooling device housing 1004 and provides an enclosure for the cooling device housing 1004. A nozzle coolant surface 1016 is formed on an end of the nozzle member 1012 opposite the nozzle member base 1014. The nozzle coolant surface 1016 extends outward from a nozzle coolant surface center 1018 to a nozzle coolant surface edge 1020. The nozzle coolant surface 1016 forms a coolant chamber 1030 with the heat-generating device 101 when mounted on the device-supporting surface 1002. The nozzle member 1012 includes a nozzle body wall 1032 surrounding the nozzle member 1012 between the nozzle coolant surface 1016 and the nozzle member base 1014.

A chamber gap 1046 is formed between the nozzle body wall 1032 and the inner wall surface 1008 of the housing wall 1006 to allow the coolant to drain from the coolant chamber 1030. The nozzle member 1012 includes a nozzle ledge 1070 formed by the nozzle coolant surface edge 1020 extending over the nozzle body wall 1032. A nozzle member inner surface 1072 extends from the nozzle body wall 1032 opposite the nozzle member base 1014. A peripheral channel 1080 is formed by the nozzle ledge 1070, the nozzle body wall 1032, the nozzle member inner surface 1072, the inner wall surface 1008 of the housing wall 1004, and the chamber gap 1046.

The cooling device 1000 in FIG. 10 includes a turbulence-generating fluid inlet path 1042 in the nozzle member 1012. The turbulence-generating fluid inlet path 1042 is implemented using a plurality of swirl vanes 1050 formed in the fluid inlet path 1042. The swirl vanes 1050 may be designed to provide a desired amount of turbulence at a selected fluid velocity to enhance the cooling of the heat-generating device 101 as desired according to the selected thermal profile.

FIG. 11 is a top view of another example implementation of a cooling device 1100. The cooling device 1100 in FIG. 11 includes a spiral cooling channel 1110 formed on a back plate 1102. The back plate 1102 on the cooling device 1100 may be similar to any of the back plates described above with reference to FIGS. 1-7. The cooling device 1100 may also include a nozzle member similar to any of the nozzle members described above with reference to FIGS. 1-10. The spiral cooling channel 1110 provides a fluid path that begins at the center of the cooling device 1100 at which a fluid inlet path 1104 permits coolant to enter the spiral cooling channel 1110. The spiral cooling channel 1110 may be formed to have a volume and shape that provides maximum heat transfer at a portion of the heat-generating device 101 that generates the most heat and comparatively reduced heat transfer at portions of the heat-generating device that generate comparatively less heat. In addition, the spiral cooling channel 1110 may be formed to have a width and depth that varies along the fluid path. The varying width and depth may be configured to adjust the heat transfer from the back plate 1102 into the coolant. The geometry of the spiral cooling channel 1110 may be configured to tailor the cooling according to a selected thermal profile.

It is noted that the selected thermal profile to which the cooling function is tailored using the cooling devices described herein may not be such that an overall uniform thermal profile results during operation of the heat-generating device 101. Portions of the heat-generating device 101 may be cooled more or less to produce desired edge effects and optical properties.

Various example implementations of cooling devices configured to cool a heat-generating device according to a selected thermal profile have been described above. It is noted that various features illustrated in the example implementations may be combined to arrive at other example implementations of cooling devices that may or may not be specifically shown. One example of such a combination is described above with reference to FIG. 10 in which the turbulence-generating fluid inlet path replaces the plurality of fluid conduits and individually controlled injectors so that the heat-generating device 101 is cooled directly by convection with turbulence. An example of a combination of features that is not specifically illustrated in the drawings is a cooling device that includes a plurality of fluid conduits and fluid inlet paths individually controlled (as shown in FIG. 9) to directly cool a back plate on which the heat-generating device is mounted (as shown in FIG. 1, at least). The spiral cooling channel in FIG. 12 may be added to the back plate (as shown in FIG. 1 for example), or to the back plate 702 (shown in FIG. 7) with a nozzle member according to any of the examples described herein. Another example of such a combination of features that is also not specifically shown is a cooling device that incorporates a nozzle member of the type described with reference to FIG. 1 with a coolant chamber that lacks a back plate as shown in FIG. 9 for example. Those of ordinary skill in the art will understand how combinations of the features described above may be formed to arrive at example implementations that may not be specifically shown in the figures.

It will be understood that various aspects or details of the invention may be changed without departing from the scope of the invention. Furthermore, the foregoing description is for the purpose of illustration only, and not for the purpose of limitation—the invention being defined by the claims.

1. A cooling device comprising:
a back plate comprising a heat-receiving surface for supporting a heat-generating device, an opposing inner back plate surface, and a back plate thickness between the heat-receiving surface and the inner back plate surface;
a housing extending from the back plate and comprising a coolant outlet; and
a nozzle member disposed in the housing and spaced from the inner back plate surface to form a coolant chamber therebetween, the nozzle member comprising a coolant inlet and configured for establishing a coolant fluid flow through the coolant chamber from the coolant inlet to the coolant outlet;
wherein a shape of at least one of the back plate, the coolant chamber, and the nozzle member varies to establish a non-uniform heat transfer profile from the heat-generating device to the coolant chamber to impart a desired temperature profile in the heat-generating device.

2. The cooling device of claim 1 where:
the housing is formed by the back plate and a housing wall formed to surround the housing, the housing wall comprising an inner wall surface extending from the inner back plate surface, the housing wall surrounding the housing between a coolant access side and the back plate; and
the nozzle member is configured to generate a coolant fluid flow in the coolant chamber from the center of the coolant chamber to an outer region of the coolant chamber, to provide a chamber gap in the outer region of the coolant chamber to allow the coolant fluid to exit, where the coolant fluid flow is controlled to cool the heat-generating device according to the desired thermal profile by the shape of the coolant chamber and a fluid velocity at which the coolant fluid is added into the coolant chamber.

3. The cooling device of claim 2 where:
the nozzle member further comprises:
a nozzle member base substantially covering the coolant access side of the housing to substantially enclose the housing;
a nozzle coolant surface in the housing on an end of the nozzle member opposite the nozzle member base, the nozzle coolant surface extending outward from a nozzle coolant surface center to a nozzle coolant surface edge, and forming the coolant chamber with the inner back plate surface;
a nozzle body wall surrounding the nozzle member between the nozzle coolant surface and the nozzle member base, the chamber gap being formed between the nozzle body wall and the inner wall surface of the housing wall; and
the cooling device further comprises:
a fluid inlet path between the nozzle member base and the nozzle coolant surface, wherein the coolant inlet is configured to receive a coolant fluid, and to inject the coolant fluid in the fluid inlet path to fill the coolant chamber with coolant fluid, and the coolant outlet is configured to provide an exit for coolant fluid flowing in the chamber gap.

4. The cooling device of claim 3 where:
the nozzle member further comprises:
a nozzle ledge formed by the nozzle coolant surface edge extending over the nozzle body wall; and
a nozzle member inner surface extending from the nozzle body wall opposite the nozzle member base;
the cooling device further comprises:
a peripheral channel formed by the nozzle ledge, the nozzle body wall, the nozzle member inner surface, the inner wall surface of the housing wall, and the chamber gap, where the coolant outlet is formed in the peripheral channel.

5. The cooling device of claim 1 further comprising:
a chamber wall opening between the nozzle member base perimeter and a chamber wall edge;
a coolant exit chamber comprising an exit chamber surface extending from the nozzle member base perimeter around to the chamber wall edge forming a tube-like structure with a varying cross-sectional area that increases from a smallest cross-sectional area to a largest cross-sectional area, the coolant outlet formed to drain the coolant from the coolant exit chamber where the coolant exit chamber has the largest cross-sectional area.

6. The cooling device of claim 1 where the nozzle member comprises a nozzle coolant surface at least partially forming the coolant chamber with the inner back plate surface, the nozzle coolant surface extends outward from a nozzle coolant surface center thereof to a nozzle coolant surface edge thereof, and the nozzle coolant surface comprises:
a nozzle coolant surface contour configured to form a substantially converging volume in the housing from the nozzle coolant surface center to the nozzle coolant surface edge.

7. The cooling device of claim 1 where the nozzle member comprises a nozzle coolant surface at least partially forming the coolant chamber with the inner back plate surface, the nozzle coolant surface extends outward from a nozzle coolant surface center thereof to a nozzle coolant surface edge thereof, and the nozzle coolant surface comprises:
a nozzle coolant surface contour configured to form a substantially diverging volume in the housing from the nozzle coolant surface center to the nozzle coolant surface edge.

8. The cooling device of claim 1 comprising a fluid inlet path from the coolant inlet to the coolant chamber, where:
the fluid inlet path comprises swirl vanes configured to provide a swirling fluid path through the fluid inlet path.

9. The cooling device of claim 1 where the nozzle member comprises a nozzle coolant surface at least partially forming the coolant chamber with the inner back plate surface, and further comprising:
a plurality of fluid inlet paths distributed through the nozzle member and extending to the nozzle coolant surface; and
a plurality of fluid conduits extending from corresponding fluid inlet paths, the plurality of fluid conduits configured to connect to coolant fluid jets individually controlled to inject coolant fluid to contact the inner back plate surface.

10. The cooling device of claim 1 where the coolant chamber is a first coolant chamber, the back plate comprising:
a second coolant chamber formed with a cross-sectional area parallel with the heat-generating device of at least a heat-generating surface area, the second coolant chamber disposed to contain a coolant fluid.

11. The cooling device of claim 10 further comprising:
a coolant inlet formed on the second coolant chamber to provide entry for coolant fluid; and
a coolant outlet formed on the second coolant chamber to provide exit for coolant fluid.

12. A cooling device comprising:
a device-supporting surface on which a heat-generating device is mounted, the device-supporting surface having an area sufficient to contact a surface of the heat-generating device along a peripheral area substantially along a perimeter of the heat-generating device;
a housing extending from the heat-generating device when mounted on the device-supporting surface, the housing comprising a coolant outlet; and
a nozzle member disposed in the housing and spaced from the heat-generating device when mounted on the device-supporting surface to form a coolant chamber therebetween, the nozzle member comprising a coolant inlet and configured for establishing a coolant fluid flow through the coolant chamber from the coolant inlet to the coolant outlet;
wherein a shape of at least one of the coolant chamber and the nozzle member varies to establish a non-uniform heat transfer profile from the heat-generating device to the coolant chamber to impart a desired temperature profile in the heat-generating device.

13. The cooling device of claim 12 where:
the housing wall comprises an inner wall surface extending from the device-supporting surface, the housing wall surrounding the housing between a coolant access side and the device-supporting surface;
the nozzle member is configured to generate a coolant fluid flow in the coolant chamber from the center of the coolant chamber to an outer region of the coolant chamber, to provide a chamber gap in the outer region of the coolant chamber to allow the coolant fluid to exit, where the coolant fluid flow is controlled to cool the heat-generating device according to the desired thermal profile by the shape of the coolant chamber and a fluid velocity at which the coolant fluid is added into the coolant chamber.

14. The cooling device of claim 13 where:
the nozzle member further comprises:
a nozzle member base substantially covering the coolant access side of the housing to substantially enclose the housing;
a nozzle coolant surface in the housing on an end of the nozzle member opposite the nozzle member base, the nozzle coolant surface extending outward from a nozzle coolant surface center to a nozzle coolant surface edge, and forming the coolant chamber with the heat-generating device when mounted on the device-supporting surface;
a nozzle body wall surrounding the nozzle member between the nozzle coolant surface and the nozzle member base, the chamber gap being formed between the nozzle body wall and the inner wall surface of the housing wall; and
the cooling device further comprises a fluid inlet path between the nozzle member base and the nozzle coolant surface, wherein the coolant inlet is configured to receive the coolant fluid, and to inject the coolant fluid in the fluid inlet path to fill the coolant chamber with coolant fluid, and the coolant outlet is configured to provide an exit for coolant fluid flowing in the chamber gap.

15. The cooling device of claim 13 where:
the nozzle member further comprises:
a nozzle ledge formed by the nozzle coolant surface edge extending over the nozzle body wall; and
a nozzle member inner surface extending from the nozzle body wall opposite the nozzle member base; and
the cooling device further comprises:
a peripheral channel formed by the nozzle ledge, the nozzle body wall, the nozzle member inner surface, the inner wall surface of the housing wall, and the chamber gap, where the coolant outlet is formed in the peripheral channel.

16. The cooling device of claim 12 further comprising:
a chamber wall opening between the nozzle member base perimeter and a chamber wall edge;
a coolant exit chamber comprising an exit chamber surface extending from the nozzle member base perimeter around to the chamber wall edge forming a tube-like structure with a varying cross-sectional area that increases from a smallest cross-sectional area to a largest cross-sectional area, the coolant outlet formed to drain the coolant from the coolant exit chamber where the coolant exit chamber has the largest cross-sectional area.

17. The cooling device of claim 12 where the nozzle member comprises a nozzle coolant surface, and the nozzle coolant surface comprises:
a nozzle coolant surface contour configured to vary the distance between the heat-generating device and nozzle coolant surface according to the desired thermal profile of the heat-generating device.

18. The cooling device of claim 12 comprising a fluid inlet path from the coolant inlet to the coolant chamber, where:
the fluid inlet path comprises swirl vanes configured to provide a swirling fluid path through the fluid inlet path.

19. The cooling device of claim 12 the nozzle member comprises a nozzle coolant surface at least partially forming the coolant chamber, and further comprising:
a plurality of fluid inlet paths distributed through the nozzle member and extending to the nozzle coolant surface; and
a plurality of fluid conduits extending from corresponding fluid inlet paths, the plurality of fluid conduits configured to connect to coolant fluid jets individually controlled to inject coolant fluid to contact the heat-generating device according to the thermal profile of the heat-generating device.

20. A method for cooling a heat-generating device comprising:
injecting a cooling fluid into a fluid inlet path formed through a center of a nozzle member disposed in a housing, the fluid inlet path opening at a nozzle member coolant surface opposite a coolant access side of the nozzle member, the nozzle member coolant surface forming a coolant chamber with an inner back plate surface of a back plate comprising a device-supporting surface on a heat-conducting solid with a varying thickness according to the desired thermal profile of the heat-generating device, the varying thickness increasing in thickness where the heat-generating device generates decreasing heat;
draining the cooling fluid from the coolant chamber through a chamber gap surrounding the nozzle member and into a coolant outlet;
providing a coolant fluid flow in the coolant chamber at a selected fluid velocity by controlling an inlet fluid velocity in the fluid inlet path, the coolant fluid flow providing convection cooling of the heat-generating device by initially contacting the inner back plate surface at a portion of the back plate having least thickness and flowing along the inner back plate surface towards a portion of the back plate having greatest thickness;
where the step of providing the coolant fluid flow comprises determining the selected fluid velocity in the fluid inlet path based on a balanced inflow and outflow of cooling fluid into and out of the coolant chamber for a coolant chamber volume and coolant volume shape.

21. The method of claim 20 where the step of draining the cooling fluid comprises:
receiving the cooling fluid via the chamber gap into a peripheral channel surrounding the nozzle member; and
permitting the cooling fluid to flow the coolant outlet formed in the peripheral channel.

22. The method of claim 20 where the step of draining the cooling fluid comprises:
receiving the cooling fluid via the chamber gap into a coolant exit chamber comprising an exit chamber surface extending from a nozzle member base perimeter around to a chamber wall edge to form a tube-like structure with a varying cross-sectional area that increases from a smallest cross-sectional area to a largest cross-sectional area, the coolant outlet formed to drain the coolant from the coolant exit chamber where the coolant exit chamber has the largest cross-sectional area.

23. The method of claim 20 where the step of providing the coolant fluid flow in the coolant chamber at the selected velocity comprises:
determining the selected fluid velocity in the fluid inlet path for a diverging coolant chamber formed by the inner back plate surface and the nozzle coolant surface diverging towards a nozzle member edge.

24. The method of claim 20 where the step of providing the coolant fluid flow in the coolant chamber at the selected velocity comprises:
determining the selected fluid velocity in the fluid inlet path for a converging coolant chamber formed by the inner back plate surface and the nozzle coolant surface converging towards a nozzle member edge.

25. The method of claim 20 where the step of injecting the cooling fluid into the fluid inlet path comprises:
providing a turbulent flow to the coolant flow in the coolant chamber directed at a highest-temperature region where the fluid inlet path is formed with swirl vanes along at least a portion of a length of the fluid inlet path.

26. A method for cooling a heat-generating device comprising:
injecting a cooling fluid into a fluid inlet path formed through a center of a nozzle member disposed in a housing, the fluid inlet path opening at a nozzle member coolant surface opposite a coolant access side of the nozzle member, the nozzle member coolant surface forming a coolant chamber with a first side of the heat-generating device when the heat-generating device is mounted on a device-supporting surface of a chamber wall formed to enclose the housing;
draining the cooling fluid from the coolant chamber through a chamber gap surrounding the nozzle member and into a coolant outlet;
providing a coolant fluid flow in the coolant chamber at a selected fluid velocity by controlling an inlet fluid velocity in the fluid inlet path, the coolant fluid flow providing convection cooling of the heat-generating device by initially contacting the heat-generating device at a portion of the heat-generating device generating the most heat and flowing along the heat-generating device towards the nozzle member edge;
where the step of providing the coolant fluid flow comprises determining the selected fluid velocity in the fluid inlet path based on a balanced inflow and outflow of cooling fluid into and out of the coolant chamber for a coolant chamber volume and coolant volume shape.

27. The method of claim 26 where the step of draining the cooling fluid comprises:
receiving the cooling fluid via the chamber gap into a peripheral channel surrounding the nozzle member; and
permitting the cooling fluid to flow the coolant outlet formed in the peripheral channel.

28. The method of claim 26 where the step of draining the cooling fluid comprises:
receiving the cooling fluid via the chamber gap into a coolant exit chamber comprising an exit chamber surface extending from a nozzle member base perimeter around to a chamber wall edge to form a tube-like structure with a varying cross-sectional area that increases from a smallest cross-sectional area to a largest cross-sectional area, the coolant outlet formed to drain the coolant from the coolant exit chamber where the coolant exit chamber has the largest cross-sectional area.

29. The method of claim 26 where the step of injecting the cooling fluid into the fluid inlet path comprises:
providing a turbulent flow to the coolant flow in the coolant chamber directed at a highest-temperature region where the fluid inlet path is formed with swirl vanes along at least a portion of a length of the fluid inlet path.

30. A method for cooling a heat-generating device comprising:
injecting a cooling fluid into a plurality of fluid inlet paths formed through a nozzle member disposed in a housing, the plurality of fluid inlet paths opening at a nozzle member coolant surface opposite a coolant access side of the nozzle member, the nozzle member coolant surface forming a coolant chamber with a first side of the heat-generating device when the heat-generating device is mounted on a device-supporting surface of a chamber wall formed to enclose the housing;
draining the cooling fluid from the coolant chamber through a chamber gap surrounding the nozzle member and into a coolant outlet;
providing a coolant fluid flow in the coolant chamber at a selected fluid velocity in each of the plurality of fluid inlet paths by individually controlling an inlet fluid velocity in each of the plurality of the fluid inlet paths, the coolant fluid flow providing convection cooling of the heat-generating device by controlling the inlet fluid velocity of each fluid inlet path to provide the greatest heat transfer at the portion of the heat-generating device that generates the most heat.

31. The method of claim 30 where the step of draining the cooling fluid comprises:
receiving the cooling fluid via the chamber gap into a peripheral channel surrounding the nozzle member; and
permitting the cooling fluid to flow the coolant outlet formed in the peripheral channel.

32. The method of claim 30 where the step of draining the cooling fluid comprises:
receiving the cooling fluid via the chamber gap into a coolant exit chamber comprising an exit chamber surface extending from a nozzle member base perimeter around to a chamber wall edge to form a tube-like structure with a varying cross-sectional area that increases from a smallest cross-sectional area to a largest cross-sectional area, the coolant outlet formed to drain the coolant from the coolant exit chamber where the coolant exit chamber has the largest cross-sectional area.

33. The method of claim 30 where the step of providing the coolant fluid flow in the coolant chamber comprises determining the selected fluid velocity for each of the plurality of fluid inlet paths based on a proximity of the nozzle member contour surface to the heat-generating device at each of the plurality of fluid inlet paths.

34.-41. (canceled)
